(19) United States
(12) Patent Application Publication
(10) Pub. No.: US 2008/0128110 A1
(43) Pub. Date: Jun. 5, 2008

(54) HEAT SINK ASSEMBLY HAVING A FAN MOUNTING DEVICE

(75) Inventors: CHENG-TIEN LAI, Tu-Cheng (TW); CUI-JUN LU, Shenzhen (CN); SONG-SHUI LIU, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/565,517

(22) Filed: Nov. 30, 2006

(51) Int. Cl. H05K 7/20

(52) U.S. Cl. 165/80.3; 361/697

(57) ABSTRACT

A heat sink assembly comprises a heat sink (10) having a plurality of outwardly extending fins (13), a plurality of fasteners (20) and a fan (30) mounted on the heat sink (10) via the fasteners (20). Each of the fasteners (20) comprises a self-tapping screw (25) and a fan holder (22). The fan holder (22) is buckled on the fins (13) and comprises a retaining body (220). The retaining body (220) of each fan holder (22) spans cross each corner of the heat sink (10). A connecting portion (225) extends downwardly from the retaining body (220). The connecting portion (225) abuts against the fins (13) of the heat sink (10). Each self-tapping screw (25) is inserted into a hole (228) defined in the connecting portion (225) and a space between two adjacent fins (13a) of the heat sink (10) to attach the fan holder (22) to the heat sink (10).

### CROSS-REFERENCES TO RELATED APPLICATION

This application is related to U.S. patent application Ser. No. 11/164,095 filed on Nov. 22, 2005 and entitled “HEAT SINK ASSEMBLY HAVING A FAN MOUNTING DEVICE”; the co-pending U.S. patent application is assigned to the same assignee as the present application. The disclosure of the above-identified application is incorporated herein by reference.

### BACKGROUND OF THE INVENTION

1. Field of the Invention

The present invention relates generally to a heat sink assembly, and particularly to a heat sink assembly for cooling an electronic element such as a CPU by the use of a heat sink which is mounted with a fan via a fan holder.

2. Description of Related Art

A computer central processing unit (CPU) is the core controlling unit of electrical signals in most contemporary personal computers. Continued development of CPUs has enabled them to perform more and more functions. Heat generated by the CPUs has increased enormously. Such heat can adversely affect the operational stability of the computers. Measures must be taken to efficiently remove the heat from the CPU. Typically, a heat sink having high heat conductivity is mounted on the CPU to remove heat therefrom. A fan is often attached to the heat sink to provide forced airflow to the heat sink.

A related heat sink assembly as shown in FIG. 5 includes a fan 30a and a heat sink 10a. The fan 30a defines four through holes 310a in four corners thereof. The heat sink 10a comprises a base 14a for contacting with a heat-generating electronic device, and a plurality of parallel fins 15a extending upwardly from the base 14a. A threaded hole 16a is formed between two outmost fins 15a and at each of four corners of the heat sink 10a. Four screws 70a are extended through the through holes 310a and engaged in the threaded holes 16a, respectively. Thus, the fan 30a is securely mounted on the heat sink 10a. However, the process of forming the threaded holes 16a is unduly time-consuming and raises production costs. Furthermore, the outmost fins 15a are prone to deform under pressure from the screws 70a. This can lead to a breakage of the outmost fins 15a. Furthermore, in operation, the screws 70a are prone to be loosened by vibration and make noise.

### SUMMARY OF THE INVENTION

Accordingly, what is needed is a heat sink assembly having a fan holder for facilitating firm fastening of a fan to a heat sink.

A heat sink assembly in accordance with the present invention comprises a heat sink having a plurality of outwardly extending fins, a plurality of fasteners and a fan mounted on the heat sink via the fasteners. Each of the fasteners comprises a self-tapping screw and a fan holder. The fan holder is buckled with the fins and comprises a retaining body. The retaining body of each fan holder spans across each corner of the heat sink. A connecting portion extends downwardly from the retaining body. The connecting portion abuts against the fins of the heat sink. Each self-tapping screw is inserted into a hole defined in the connecting portion and a space between two adjacent fins of the heat sink to attach the fan holder to the heat sink.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a heat sink assembly according to a preferred embodiment of the present invention;

FIG. 2 is an enlarged view of a fan holder of a fastener of the heat sink assembly of FIG. 1;

FIG. 3 is an assembled view of a plurality of the fasteners, a heat sink, a mounting seat, a CPU and a circuit board of the heat sink assembly of FIG. 1;

FIG. 4 is an assembled view of FIG. 1; and

FIG. 5 is an assembled view of a related heat sink assembly.

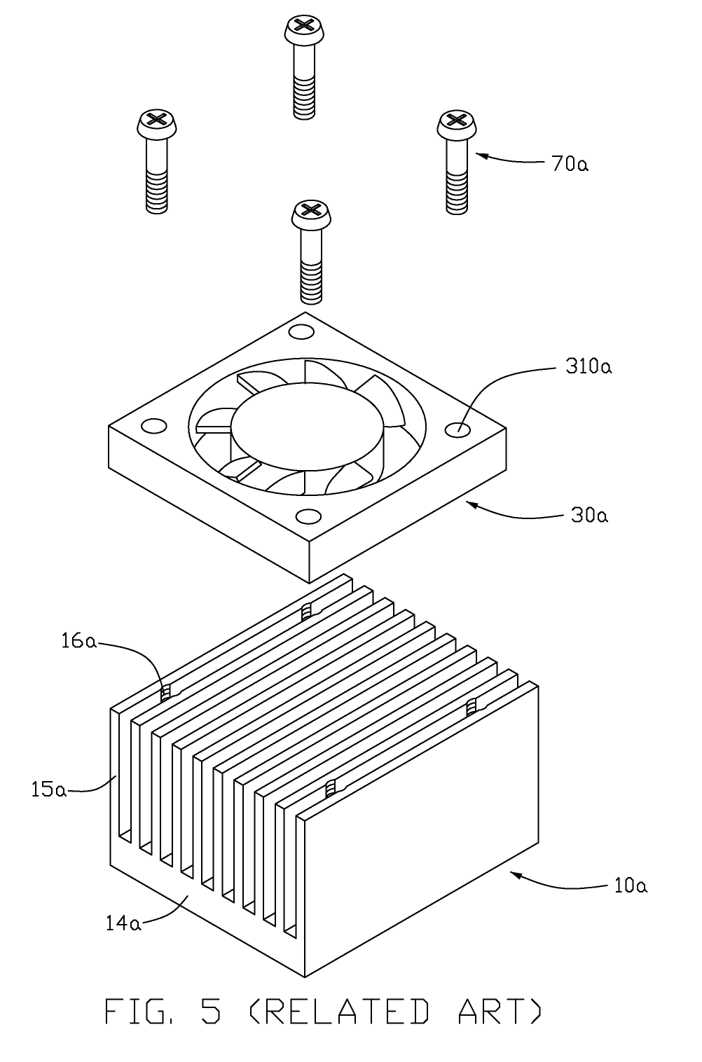

### DETAILED DESCRIPTION OF THE INVENTION

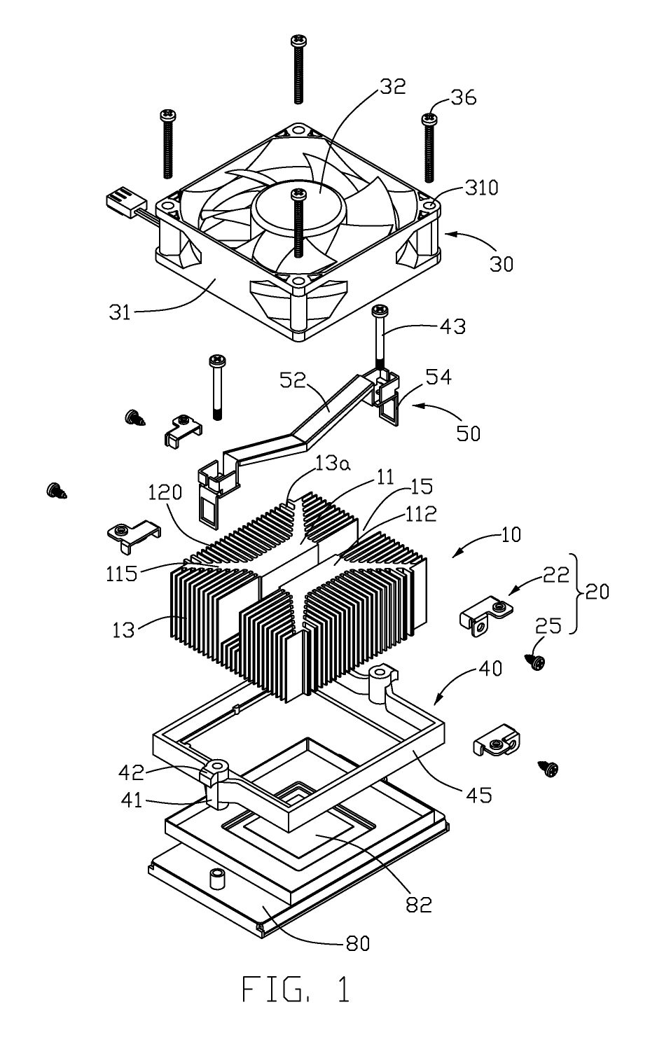

FIG. 1 illustrates a heat sink assembly in accordance with a preferred embodiment of the present invention. The heat sink assembly is configured (i.e., structured and arranged) for dissipating heat from an electronic component, such as a CPU 82 on a circuit board 80, comprising a heat sink 10, a plurality of fasteners 20, a fan 30 mounted on the heat sink 10 via the fasteners 20, a mounting seat 40 on the circuit board 80, and a clip 50 for fixing the heat sink 10 in the mounting seat 40 in such a manner that the heat sink 10 contacts the CPU 82.

The mounting seat 40 is a rectangular frame, comprising four sidewalls 45 surrounding an opening within which the CPU 82 is located. Two columns 41 are formed on two opposite sidewalls 45 of the mounting seat 40. The mounting seat 40 is fixed to the circuit board 80 by two screws 43 passing through the columns 41 and extending into the circuit board 80. A protrusion 42 extends laterally and outwardly from an outer side of each column 41.

The heat sink 10 is a cubic structure with a receiving channel 15 defined in a top portion thereof. The receiving channel 15 is rectangular and located at a middle of the heat sink 10, extending through the heat sink 10 and dividing the heat sink 10 into two symmetrical parts. The heat sink 10 comprises a core 11 and a plurality of first fins 13 extending outwardly from the core 11. The core comprises a cubic central portion 112 and four branches 115 extending symmetrically and outwardly from four edges of the central portion 112. The first fins 13 are divided into four groups oriented in four different directions by the four branches 115. Two neighboring groups of the first fins 13 extending from peripheries of the central portion 112 and the branches 115 are oriented perpendicularly to each other. The heat sink 10 has a substantially planar top surface 120 and a substantially planar bottom surface (not shown) positioned on an opposite side to the top surface 120. The top surface 120 of the heat sink 10 is for supporting the fan 30, and the bottom surface of the heat sink 10 is configured to thermally contact the CPU 82. The receiving channel 15 extends through two opposite groups of the first fins 13 of the heat sink 10. In the other two opposite groups, two adjacent second fins 13a extending from an end of each branch 115 are formed thicker than the first fins 13.

The clip 50 is used to engage with the mounting seat 40 so as to make the heat sink 10 fastened within the opening of the mounting seat 40 and ensure that the bottom surface of heat sink 10 is held in thermal contact with the CPU 82 for dissipating heat therefrom. The clip 50 comprises a V-like elongated pressing member 52 and two clamping legs 54 connected with two ends of the pressing member 52. During mounting of the heat sink 10, the heat sink 10 is placed in the mounting seat 40. Then, the pressing member 52 spans in the receiving channel 15 of the heat sink 10, and then the clamping members 54 are hooked to the protrusions 42 of the columns 41.

The fan 30 comprises a frame 31 and a motor 32 received in the frame 31. The frame 31 has a square configuration, and comprises four corners. A through hole 310 is defined at each corner, for permitting passage of screws 36.

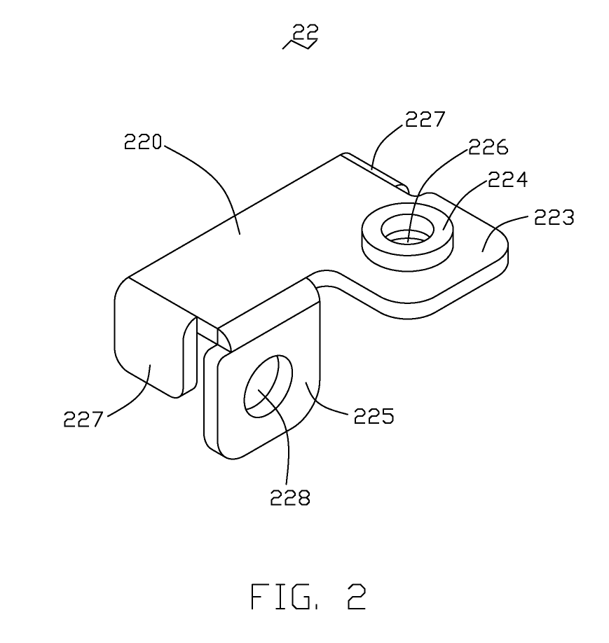

Also referring to FIG. 2, the fasteners 20, buckled with four corners of the heat sink 10, each comprises a fan holder 22 and a self-tapping screw 25, for mounting the fan 30 onto the top portion of the heat sink 10. Each fan holder 22 is formed by stamping a single piece of metal. The fan holder 22 comprises a rectangular retaining body 220. A rectangular supporting portion 223 and a rectangular connecting portion 225 separated by a gap both extend from an edge of the retaining body 220. The supporting portion 223 extends horizontally from the retaining body 220 for supporting and connecting with the fan 30. A circular step 224 is formed on the supporting portion 223. A hole 226 is defined through the step 224 and the supporting portion 223. The connecting portion 225 extends perpendicularly and downwardly from the retaining body 220 for abutting against and connecting with the heat sink 10. A hole 228 is defined in the connecting portion 225. The supporting portion 223 is perpendicular to the connecting portion 225. The retaining body 220 further comprises a pair of opposite lateral walls 227 extending perpendicularly and downwardly from two opposite edges thereof. One of the lateral walls 227 is adjacent to the supporting portion 223, and the other lateral wall 227 is adjacent to the connecting portion 225. A diameter of the self-tapping screw 25 is bigger than a space between the adjacent two second fins 13a of the heat sink 10. Furthermore, the step 224 can be formed on the retaining body 220 of the fan holder 22, meanwhile, the hole 226 can be defined in the step 224 and the retaining body 220.

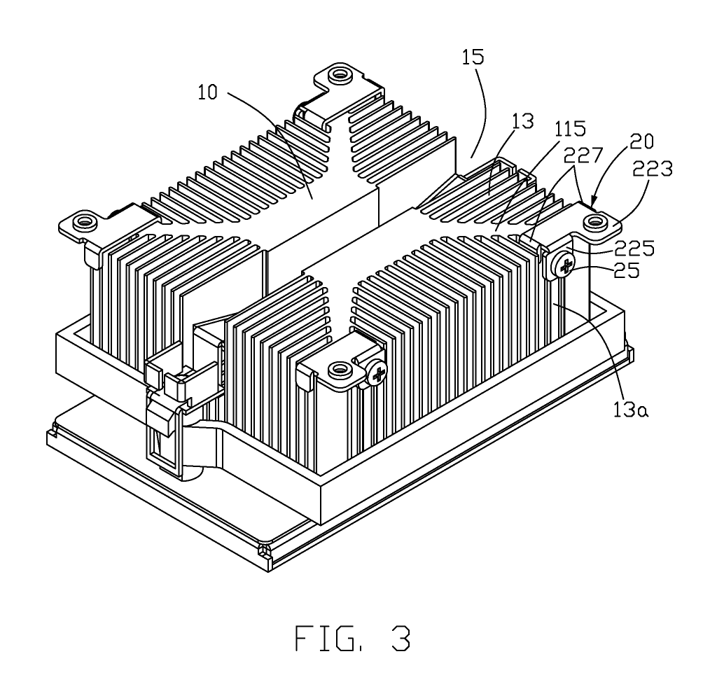

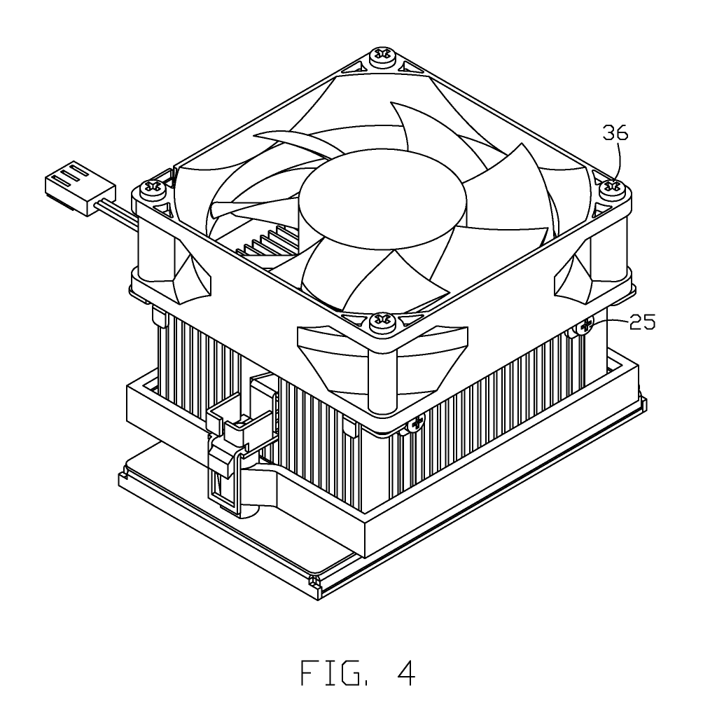

Referring to FIG. 3 and FIG. 4, in assembly of the heat sink 10 and the fan 30, the four fasteners 20 are mounted to four corners of the top surface 120 of the heat sink 10 adjacent to the second fins 13a. Each fan holder 22 spans across each corresponding corner of the heat sink 10, with an inner surface of one of the lateral walls 227 abutting against a side of the second fin 13a beside a group of the first fins 13 of the heat sink 10 and that of the other wall 227 abutting against an outer face of an adjacent group of the first fins 13 of the heat sink 10. Meanwhile, an inner surface of the connecting portion 225 abuts against an outer face of the two adjacent second fins 13a with the hole 228 positioned corresponding to a space between the second fins 13a. The step 224 of the supporting portion 223 faces upwardly and the hole 226 is aligned with the corresponding through hole 310 of the fan 30. A width of a space between the second fins 13a is smaller than an outer diameter of the self-tapping screw 25, thus the self-tapping screw 25 can be inserted into the hole 228 of the connecting portion 225 and the space between the second fins 13a, and threadedly engage with the second fins 13a by self-tapping. The second fins 13a each have a thickness large enough for preventing the second fins 13a from being overly expanded outwardly during the insertion of the screws 25, thus securely and firmly attaching the fan holder 22 to the heat sink 10. The fan 30 is then placed on the fan holder 22; each screw 36 extends through the through hole 310 of the fan 30 and fully threadedly engages in the corresponding hole 226 of the fan holder 22. Thus the fan 30 is tightly secured on the top surface 120 of the heat sink 10 via the fasteners 20 and the screws 36.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink assembly, comprising:
a heat sink comprising a plurality of outwardly extending fins;
a plurality of fasteners, each of the fasteners comprising a self-tapping screw and a fan holder, the fan holder being buckled with the fins and having a retaining body and a connecting portion extending downwardly from the retaining body; and
a fan mounted on the heat sink via the fasteners; wherein
the retaining body of each fan holder spans across each corner of the heat sink, the connecting portion of the fan holder abuts against the fins of the heat sink, each self-tapping screw is inserted into a hole defined in the connecting portion and a space between two adjacent fins of the heat sink to attach the fan holder to the heat sink.

2. The heat sink assembly as claimed in claim 1, wherein a supporting portion extends horizontally from an edge of the retaining body for supporting and connecting with the fan.

3. The heat sink assembly as claimed in claim 2, wherein a step is formed on the supporting portion and a hole is defined through the step and the supporting portion.

4. The heat sink assembly as claimed in claim 2, wherein the connecting portion and the supporting portion are perpendicular to and spaced from each other.

5. The heat sink assembly as claimed in claim 1, wherein a pair of opposite lateral walls extend downwardly from two opposite edges of the retaining body.

6. The heat sink assembly as claimed in claim 5, wherein the heat sink is cube-shaped and comprises a central portion and four branches extending from the central portion, the fins are divided into four fin groups oriented in four different directions.

7. The heat sink assembly as claimed in claim 6, wherein one of the lateral walls of the fan holder abuts against a side of one fin in a fin group of the heat sink and the other lateral wall abuts against a side of an adjacent fin group of the heat sink.

8. The heat sink assembly as claimed in claim 6, wherein the two adjacent fins used to connect the self-tapping screw extend from an end of each branch and are formed thicker than other fins.

9. The heat sink assembly as claimed in claim 8, wherein the connecting portion of the fan holder abuts against the two thicker fins and the hole of the connecting portion corresponds to a space between the two thicker fins, the self-tapping screw is inserted into the hole, the space and threadedly engage with the two thicker fins of the heat sink.

10. The heat sink assembly as claimed in claim 8, wherein the space between the two thicker fins of the heat sink is smaller than a diameter of the self-tapping screw.

11. The heat sink assembly as claimed in claim 6, wherein neighboring fin groups of the heat sink extend from peripheries of the central portion and the branches of the central portion and are oriented perpendicular to each other.

12. The heat sink assembly as claimed in claim 3, the fan comprises a square frame, the fan holders correspond to four corners of the frame, and a plurality of screws extend through the corners of the frame and threadedly engaged in the holes of the supporting portions of the fan holders.

13. A heat sink assembly, comprising:
a heat sink comprising a plurality of outwardly extending first fins and a plurality of two adjacent second fins that are formed thicker than the first fins forming in each corner of the heat sink;
a plurality of fasteners, each of the fasteners comprising a self-tapping screw and a fan holder, the fan holder buckled with the fins and having a retaining body, and a connecting portion extending downwardly from the retaining body and a pair of opposite lateral walls extending downwardly from two opposite edges of the retaining body; and
a fan mounted on the heat sink via the fasteners; wherein
the retaining body of each fan holder spans across each corner of the heat sink via the lateral walls, the connecting portion of the fan holder abuts against the second fins of the heat sink, each self-tapping screw is inserted into a hole defined in the connecting portion and a space between the two second fins of the heat sink to attach the fan holder to the heat sink.

14. The heat sink assembly as claimed in claim 13, wherein a supporting portion extends horizontally from an edge of the retaining body for supporting and connecting with the fan.

15. The heat sink assembly as claimed in claim 14, wherein a step is formed on the supporting portion and a hole is defined through the step and the supporting portion.

16. The heat sink assembly as claimed in claim 14, wherein the connecting portion and the supporting portion are perpendicular to and spaced from each other.

17. The heat sink assembly as claimed in claim 13, wherein the heat sink is cubic and comprises a central portion and four branches extending from the central portion, the fins are divided into four groups oriented in four different directions.

18. The heat sink assembly as claimed in claim 13, wherein the connecting portion of the fan holder abuts against the two thicker second fins and the hole of the connecting portion corresponds to a space between the two second fins, the self-tapping screw is inserted into the hole and the space and threadedly engages with the two second fins of the heat sink.
